(19) United States
(12) Patent Application Publication
(10) Pub. No.: US 2022/0038826 A1
(43) Pub. Date: Feb. 3, 2022

(54) DIAPHRAGM, MEMS MICROPHONE HAVING THE SAME AND METHOD OF MANUFACTURING THE SAME

(71) Applicant: DB HITEK CO., LTD., Seoul (KR)

(72) Inventor: Jin Hyung LEE, Seoul (KR)

(21) Appl. No.: 17/388,140

(22) Filed: Jul. 29, 2021

(30) Foreign Application Priority Data
Jul. 31, 2020 (KR) 10-2020-0096050

(51) Int. Cl. H04R 19/04; H04R 31/00; H04R 7/02; B81B 3/00; B81C 1/00

(52) U.S. Cl. CPC H04R 19/04; H04R 31/003; H04R 7/02; B81B 3/0021; B81B 3/001; B81C 2201/013; H04R 2201/003; B81B 2201/0257; B81B 2203/0127; B81B 2203/019; B81C 1/00158

(57) ABSTRACT

A diaphragm of a MEMS microphone is configured to generate a displacement thereof in response to an applied acoustic pressure, and the diaphragm includes a plurality of vent holes having a bent shape to increase the length of the vent holes.

### CROSS-REFERENCE TO RELATED APPLICATION

This application claims priority to Korean Patent Application No. 10-2020-0096050, filed on Jul. 31, 2020 and all the benefits accruing therefrom under 35 U.S.C. § 119, the contents of which are incorporated by reference in their entirety.

### TECHNICAL FIELD

The present disclosure relates to diaphragms, Micro-Electro-Mechanical Systems (MEMS) microphones having such diaphragms, and a method of manufacturing such MEMS microphones, and more particularly, to a diaphragm configured to generate a displacement thereof in response to an applied acoustic pressure, MEMS microphones having such diaphragm, and a method of manufacturing such MEMS microphones.

### BACKGROUND

Generally, a capacitive microphone utilizes a capacitance between a pair of electrodes which are facing each other to generate an acoustic signal. A MEMS microphone may be manufactured by a semiconductor MEMS process.

In order to apply the MEMS microphone to a mobile device such as a mobile phone, signal-to-noise ratio (SNR) of the MEMS microphone must be improved.

In order to improve the SNR, noise generated in vent holes formed in a diaphragm must be reduced.

Therefore, a configuration is required that can reduce the noise of acoustic waves passing through the vent holes of the diaphragm.

### SUMMARY

The embodiments herein provide a diaphragm capable of increasing a resistance of acoustic waves passing through the vent holes, a MEMS microphone having the diaphragm, and a method of manufacturing the MEMS microphone.

According to an example embodiment of the present invention, a diaphragm of a MEMS microphone is configured to generate a displacement thereof in response to an applied acoustic pressure, and the diaphragm includes a plurality of vent holes having a bent shape to increase the length of the vent holes.

In an example embodiment, each of the vent holes may include a lower portion extending from a lower surface of the diaphragm to an inside of the diaphragm, an intermediate portion connected to the lower portion in the inside of the diaphragm and extending in a direction parallel to the diaphragm, and an upper portion connected to the intermediate portion in the inside of the diaphragm and extending to an upper surface of the diaphragm.

According to an example embodiment of the present invention, a MEMS microphone includes a substrate presenting a vibration area, a supporting area surrounding the vibration area and a peripheral area surrounding the supporting area, the substrate defining a cavity formed in the vibration area, a diaphragm disposed in the vibration area, being spaced apart from the substrate, covering the cavity, and configured to generate a displacement thereof in response to an applied acoustic pressure, the diaphragm defining a plurality of vent holes, and a back plate disposed over the diaphragm in the vibration area, the back plate being spaced apart from the diaphragm to maintain an air gap between the back plate and the diaphragm, the back plate defining a plurality of acoustic holes, wherein the vent holes have a bent shape to increase the length of the vent holes.

In an example embodiment, each of the vent holes may include a lower portion extending from a lower surface of the diaphragm to an inside of the diaphragm, an intermediate portion connected to the lower portion in the inside of the diaphragm and extending in a direction parallel to the diaphragm, and an upper portion connected to the intermediate portion in the inside of the diaphragm and extending to an upper surface of the diaphragm.

According to an example embodiment of the present invention, a method of manufacturing a MEMS microphone includes forming a lower insulation layer on a substrate, the substrate having a vibration area, a supporting area surrounding the vibration area, and a peripheral area surrounding the supporting area; forming a diaphragm on the lower insulation layer, the diaphragm disposed in the vibration area and having a plurality of vent holes; forming an intermediate insulation layer on the lower insulation layer covering the diaphragm; forming a back plate on the intermediate insulation layer in the vibration area facing the diaphragm; and forming an upper insulation layer on the intermediate insulation layer configured to hold the back plate apart from the diaphragm, wherein the vent holes have a bent shape to increase the length of the vent holes.

In an example embodiment, forming the diaphragm may include forming a lower silicon layer on the lower insulation layer in the vibration area; patterning the lower silicon layer through an etching process to form lower portions penetrating the lower silicon layer; forming a first filling insulation layer pattern filling the lower portions; forming an intermediate silicon layer on the lower silicon layer; patterning the intermediate silicon layer through an etching process to form intermediate portions penetrating the intermediate silicon layer, and respectively connected to the lower portions; forming a second filling insulation layer pattern filling the intermediate portions; forming an upper silicon layer on the intermediate silicon layer; and patterning the upper silicon layer through an etching process to form upper portions penetrating the upper silicon layer and respectively connected to the intermediate portions, wherein each of the vent holes includes the lower portion, the intermediate portion, and the upper portion.

In an example embodiment, the intermediate insulation layer may fill the upper portions when forming the intermediate insulation layer on the lower insulation layer covering the diaphragm.

In an example embodiment, the lower insulation layer, the intermediate insulation layer, the first filling insulation layer and the second filling insulation layer may be made of the same oxide.

In an example embodiment, the method may further include patterning the back plate and the upper insulation layer to form a plurality of acoustic holes penetrating through the back plate and the upper insulation layer; patterning the substrate to form a cavity in the vibration area to partially expose the lower insulation layer; and performing an etching process whereby an etchant is passed through the cavity and the acoustic holes to remove portions of the intermediate insulation layer, the lower insulation layer, the first filling insulation layer pattern, and the second filling insulation layer pattern, each of the removed portions located at positions corresponding the vibration area and the supporting area.

In an example embodiment, the vent holes may provide passage for the etchant during the etching process.

According to example embodiments of the present invention as described above, the vent holes are configured in the diaphragm to have a bent shape. Since a length of the vent holes is increased, the resistance acting on the acoustic waves passing through the vent holes may increase. As a result, since the vent holes may be remarkably weakened a noise component of a high frequency in the acoustic wave as compared with the conventional vent hole, and a SNR of the MEMS microphone may be improved.

The above summary is not intended to describe each illustrated embodiment or every implementation of the subject matter hereof. The figures and the detailed description that follow more particularly exemplify various embodiments.

### BRIEF DESCRIPTION OF THE DRAWINGS

Example embodiments can be understood in more detail from the following description taken in conjunction with the accompanying drawings, in which:

FIG. 1 is a plan view illustrating a MEMS microphone in accordance with an example embodiment of the present disclosure;

FIG. 2 is a cross sectional view taken along a line I-I′ of FIG. 1;

FIG. 3 is an enlarged view illustrating a portion of the diaphragm having vent holes of FIG. 2;

FIG. 4 is a plan view illustrating the diaphragm having vent holes of FIG. 3;

FIG. 5 is a flow chart illustrating a method of manufacturing a MEMS microphone in accordance with an example embodiment of the present disclosure; and

FIGS. 6 to 21 are cross sectional views illustrating a method of manufacturing a MEMS microphone in accordance with an example embodiment of the present disclosure.

### DETAILED DESCRIPTION OF EMBODIMENTS

Hereinafter, specific embodiments will be described in more detail with reference to the accompanying drawings. The present invention may, however, be embodied in different forms and should not be construed as limited to the embodiments set forth herein.

As an explicit definition used in this application, when a layer, a layer, a area or a plate is referred to as being ‘on’ another one, it can be directly on the other one, or one or more intervening layers, layers, areas or plates may also be present. By contrast, it will also be understood that when a layer, a layer, a area or a plate is referred to as being ‘directly on’ another one, it is directly on the other one, and one or more intervening layers, layers, areas or plates do not exist. Also, although terms such as a first, a second, and a third are used to describe various components, compositions, areas, layers, and layers in various embodiments of the present invention, such elements are not limited to these terms.

Furthermore, and solely for convenience of description, elements may be referred to as “above” or “below” one another. It will be understood that such description refers to the orientation shown in the Figure being described, and that in various uses and alternative embodiments these elements could be rotated or transposed in alternative arrangements and configurations.

In the following description, the technical terms are used only for explaining specific embodiments while not limiting the scope of the present invention. Unless otherwise defined herein, all the terms used herein, which include technical or scientific terms, may have the same meaning that is generally understood by those skilled in the art.

The depicted embodiments are described with reference to schematic diagrams of some embodiments of the present invention. Accordingly, changes in the shapes of the diagrams, for example, changes in manufacturing techniques and/or allowable errors, are sufficiently expected. The figures are not necessarily drawn to scale. Accordingly, embodiments of the present invention are not described as being limited to specific shapes of areas described with diagrams and include deviations in the shapes and also the areas described with drawings are entirely schematic and their shapes do not represent accurate shapes and also do not limit the scope of the present invention.

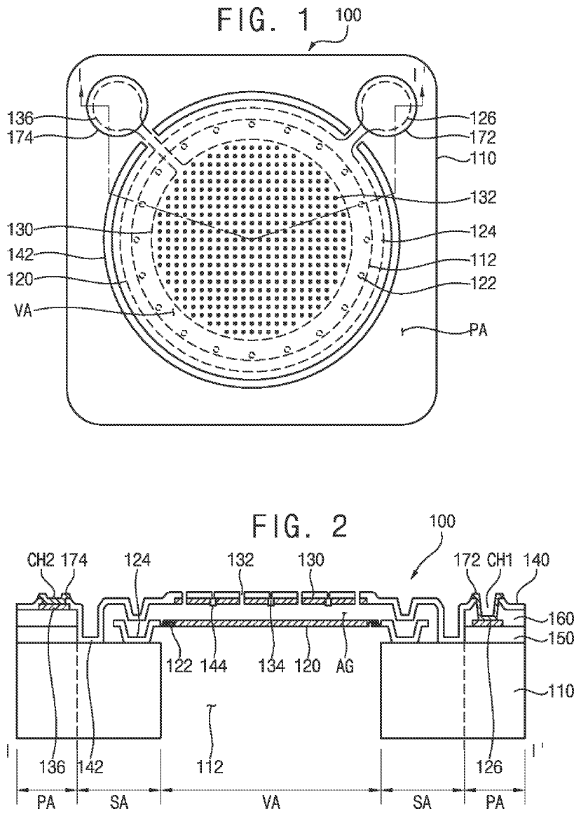

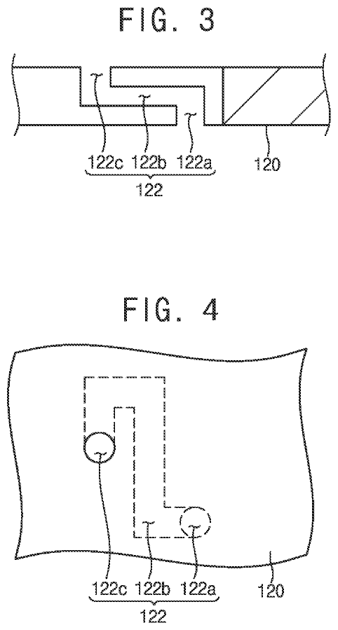

FIG. 1 is a plan view illustrating a MEMS microphone in accordance with an example embodiment of the present invention. FIG. 2 is a cross sectional view taken along a line I-I′ of FIG. 1. FIG. 3 is an enlarged view illustrating a diaphragm having vent holes shown in FIG. 2. FIG. 4 is a plan view illustrating the diaphragm having the vent holes of FIG. 3.

Referring to FIGS. 1 to 4, a MEMS microphone 100 in accordance with an example embodiment of the present invention is capable of generating a displacement in response to an applied acoustic pressure to convert an acoustic wave into an electrical signal and output the electrical signal. The MEMS microphone 100 includes a substrate 110, a diaphragm 120 and a back plate 130.

The substrate 110 is divided into a vibration area VA, a supporting area SA surrounding the vibration area VA, and a peripheral area PA surrounding the supporting area SA. In the vibration area VA of the substrate 110, a cavity 112 is formed to provide a space into which the diaphragm 120 is bendable due to the acoustic pressure. The cavity 112 is defined by a cavity wall.

In an example embodiment, the cavity 112 may have a cylindrical shape. Further, the cavity 112 may be formed in the vibration area VA to have a shape and a size corresponding to those of the vibration area VA.

The diaphragm 120 may be disposed over the substrate 110. The diaphragm 120 may generate the displacement in response to the applied acoustic pressure. The diaphragm 120 may have a membrane structure. The diaphragm 120 may cover the cavity 112. The diaphragm 120 may have a lower surface that is exposed to the cavity 112. The diaphragm 120 may have an upper surface that is exposed to an air gap AG. The diaphragm 120 is bendable in response to the applied acoustic pressure, and the diaphragm 120 is spaced apart from the substrate 110.

The diaphragm 120 may have a doped portion which is doped with impurities through an ion implantation process. The doped portion may be positioned to correspond to the back plate 130. In an example embodiment, the diaphragm 120 may have a shape of a circular disc.

An anchor 124 is positioned at an end portion of the diaphragm 120. The anchor 124 is positioned in the supporting area SA of the substrate 110. The anchor 124 supports the diaphragm 120. The anchor 124 may extend from a periphery of the diaphragm 120 toward the substrate 110 to space the diaphragm 120 from the substrate 110.

In an example embodiment of the present invention, the anchor 124 may be integrally formed with the diaphragm 120. The anchor 124 may have the lower surface to make contact with and to fix to the upper surface of the substrate 110.

In an example embodiment of the present invention, though not shown in detail in figures, the anchor 124 may be plural and may be disposed along a circumference of the diaphragm 120. Specifically, the anchors 124 may have a columnar shape spaced apart from each other. Each of the anchors 124 may have a U-shaped vertical section. In particular, an empty space may be formed between two adjacent anchors among the anchors 124, and the space may act as a passage through which the acoustic wave moves.

In addition, the diaphragm 120 may have a plurality of vent holes 122. The vent holes 122 may be arranged along the anchor 124 in a ring shape and may be spaced apart from one another. The vent holes 122 are located about a circle having a diameter smaller than the inner diameter of the anchor 124 (i.e., positions inside of the anchor 124 in a horizontal direction). Each of the vent holes 122 may serve as a passage for the applied acoustic wave. Further, each of the vent holes 122 may also function as a passage for an etchant to be used in a process of manufacturing the MEMS microphone 100.

The vent holes 122 may be positioned in the vibration area VA. Alternatively, the vent holes 122 may be positioned in a boundary area between the vibration area VA and the supporting area SA or in the supporting area SA adjacent to the vibration area VA.

The vent holes 122 penetrate through the diaphragm 120 from the lower surface to the upper surface. The vent holes 122 can comprise channels that have a bent shape and penetrate through the diaphragm 120. Accordingly, a length of the vent holes 122 may be increased as compared to vent holes 122 that penetrate directly through the diaphragm 120 perpendicular to the plain of diaphragm 120.

Specifically, each of the vent holes 122 may include a lower portion 122a, an intermediate portion 122b, and an upper portion 122c. Each of lower portion 122a, intermediate portion 122b, and upper portion 122c can be communicably coupled such that each of the vent holes 122 defines a channel from the lower surface of the diaphragm 120 to the upper surface of the diaphragm 120.

The lower portion 122a extends from a lower surface of the diaphragm 120 to an inside of the diaphragm 120.

The intermediate portion 122b is connected to the lower portion 122a in the inside the diaphragm 120 and extends in a direction parallel to the diaphragm 120. The intermediate portion 122b may have various shapes, such as a straight shape, a bent straight shape, a curved shape, and the like.

The upper portion 122c is connected to the intermediate portion 122b inside the diaphragm 120 and extends to an upper surface of the diaphragm 120.

The lower portion 122a and the upper portion 122c may be spaced apart from each other in a direction parallel to the major plane of the diaphragm 120 so that the vent holes 122 have a bent shape.

In an example embodiment of the present invention, the lower portion 122a and the upper portion 122c may be spaced apart from each other in a radial direction of a diaphragm 120 having a circular disc shape.

In an example embodiment of the present invention, the lower portion 122a and the upper portion 122c may be spaced apart from each other along a circumferential direction of the diaphragm 120 having a circular disc shape.

Since each of the vent holes 122 includes the lower portion 122a, the intermediate portion 122b, and the upper portion 122c, the length of the vent holes 122 may be sufficiently increased while maintaining the thickness of the diaphragm 120 constant as compared with the conventional vent holes penetrating a diaphragm vertically.

Also, since the length of the vent holes 122 is increased, resistance acting on the acoustic wave passing through the vent holes 122 may increase. As a result, since the vent holes 122 may be remarkably weakened a noise component of a high frequency in the acoustic wave, as compared with the conventional vent hole, may be improved, thereby improving a signal-to-noise ratio (SNR) of the MEMS microphone.

The back plate 130 may be disposed over the diaphragm 120. The back plate 130 may be disposed in the vibration area VA to face the diaphragm 120. The back plate 130 may have a doped portion which is formed by doping impurities through an ion implantation process. The back plate 130 may have a shape of a circular disc in embodiments.

In an example embodiment, the MEMS microphone 100 may further include an upper insulation layer 140 and a strut 142 for holding the back plate 130 apart from the substrate 110.

In embodiments, the upper insulation layer 140 is positioned over the substrate 110 over which the back plate 130 is positioned. The upper insulation layer 140 may cover the back plate 130 to hold the back plate 130. Thus, the upper insulation layer 140 may space the back plate 130 from the diaphragm 120. Also, the back plate 130 and the upper insulation layer 140 are spaced apart from the diaphragm 120 to make the diaphragm 120 freely bendable in response to an applied acoustic pressure. Further, an air gap AG is formed between the diaphragm 120 and the back plate 130.

A plurality of acoustic holes 132 may be formed through the back plate 130 such that the acoustic wave may flow or pass through the acoustic holes 132. The acoustic holes 132 may be formed through the upper insulation layer 140 and the back plate 130 to communicate with the air gap AG.

The back plate 130 may include a plurality of dimple holes 134. Further, a plurality of dimples 144 may be positioned in the dimple holes 134. The dimple holes 134 may be formed through the back plate 130. The dimples 144 may be positioned to correspond to positions at which the dimple holes 134 are formed.

The dimples 144 may prevent the diaphragm 120 from being coupled to a lower face of the back plate 130, inhibiting a known issue of conventional MEMS microphones.

When the acoustic pressure is applied to the diaphragm 120, the diaphragm 120 can be bent in a generally semispherical or paraboloid shape toward the back plate 130, and then can return to its initial position. The degree of bending of the diaphragm 120 may vary depending on a magnitude of the applied acoustic pressure and may be increased to such an extent that an upper surface of the diaphragm 120 makes contact with the lower surface of the back plate 130. If the diaphragm 120 is bent so much as to contact the back plate 130, the diaphragm 120 may attach to the back plate 130 and may not return to the initial position. According to example embodiments, the dimples 144 may protrude from the lower surface of the back plate 130 toward the diaphragm 120. Even when the diaphragm 120 is so deformed that the diaphragm 120 contacts the back plate 130, the dimples 144 may keep the diaphragm 120 and the back plate 130 sufficiently separated from each other that the diaphragm 120 is able to return to the initial position.

The strut 142 may be positioned in the supporting area SA and near the boundary between the supporting area SA and the peripheral area PA. The strut 142 may support the upper insulation layer 140 to space the upper insulation layer 140 and the back plate 130 from the diaphragm 120. The strut 142 may extend from a periphery of the upper insulation layer 140 toward the substrate 110. As shown in FIG. 2, the strut 142 may include a lower surface in contact with the upper surface of the substrate 110.

The strut 142 may be spaced in a radial direction from the diaphragm 120 and may be outwardly positioned away from the anchor 124. The strut 142 may have a ring shape to surround the diaphragm 120, as shown in FIG. 1.

In an example embodiment, the strut 142 may be integrally formed with the upper insulation layer 140. The strut 142 may have a U-shaped vertical section, as shown in FIG. 2.

In an example embodiment, the MEMS microphone 100 may further include a lower insulation layer 150, a diaphragm pad 126, an intermediate insulation layer 160, a back plate pad 136, a first pad electrode 172 and a second pad electrode 174.

In particular, the lower insulation layer 150 may be disposed on the upper surface of the substrate 110 and under the upper insulation layer 140. The lower insulation layer 150 may be located in the peripheral area PA, and may be disposed outside the strut 142.

The diaphragm pad 126 may be formed on an upper surface of the lower insulation layer 150. The diaphragm pad 126 may be located in the peripheral area PA. The diaphragm pad 126 may be electrically connected to the diaphragm 120 and may be doped with impurities. Though not shown in detail in figures, a connection portion may be doped with impurities to connect the doped portion of the diaphragm 120 to the diaphragm pad 126.

The intermediate insulation layer 160 may be formed on the lower insulation layer 150 on which the diaphragm pad 126 is formed.

The intermediate insulation layer 160 is positioned between the lower insulation layer 150 and the upper insulation layer 140. The intermediate insulation layer 160 are located in the peripheral area PA, and are disposed outside of the outer perimeter of the strut 142.

Further, the lower insulation layer 150 and the intermediate insulation layer 160 may be formed using a material different from that of the upper insulation layer 140. In an example embodiment, the upper insulation layer 140 may be made of a nitride such as silicon nitride, and the lower insulation layer 150 and the intermediate insulation layer 160 may be made of an oxide.

The back plate pad 136 may be formed on an upper face of the intermediate insulation layer 160. The back plate pad 136 may be located in the peripheral area PA. The back plate pad 136 may be electrically connected to the back plate 130 and may be doped with impurities by an ion implantation process. Though not shown in detail in figures, a connection portion may be doped with impurities to connect the back plate 130 to the back plate pad 136.

The first and second pad electrodes 172 and 174 may be disposed on the upper insulation layer 140 and in the peripheral area PA. The first pad electrode 172 is located over the diaphragm pad 126 to make contact with the diaphragm pad 126. On the other hand, the second pad electrode 174 is located over the back plate pad 136 to make contact with the back plate pad 136.

A first contact hole CH1 is formed by penetrating through the upper insulation layer 140 and the intermediate insulation layer 160 to expose the diaphragm pad 126, and the first pad electrode 172 makes contact with the diaphragm pad 126 exposed by the first contact hole CH1. Further, a second contact hole CH2 is formed by penetrating through the upper insulation layer 140 to expose the back plate pad 136, and the second pad electrode 174 is formed in the second contact hole CH2 to make contact with the back plate pad 136 exposed by the second contact hole CH2.

As described above, the vent holes 122 of the diaphragm 120 have a bent shape and penetrate through the diaphragm 120 so that the length of the vent holes 122 may be increased. Since the length of the vent holes 122 is increased, resistance acting on the acoustic wave passing through the vent holes 122 may increase. As a result, since the vent holes 122 may be remarkably weakened a noise component of a high frequency in the acoustic wave as compared with the conventional vent hole, and a signal-to-noise ratio (SNR) of the MEMS microphone may be improved.

In addition, the strut 142 has a ring shape and is disposed to surround the diaphragm 120. Accordingly, in a manufacturing process of the MEMS microphone 100, the struct 142 may function to define the moving area of the etchant for removing the intermediate insulation layer 160 and the lower insulation layer 150.

Hereinafter, a method of manufacturing a MEMS microphone will be described in detail with reference to the drawings.

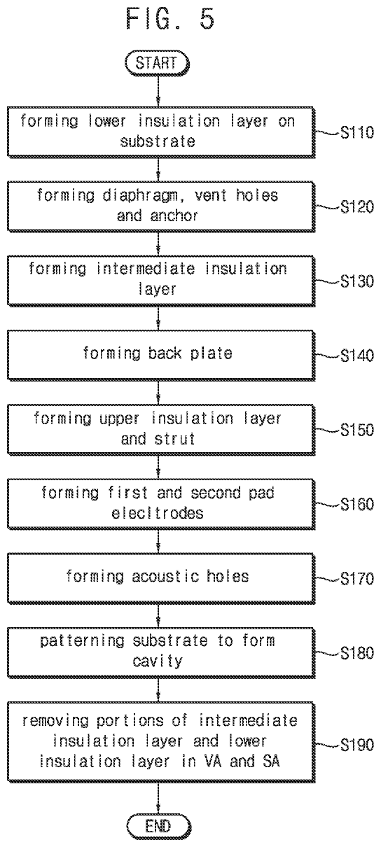

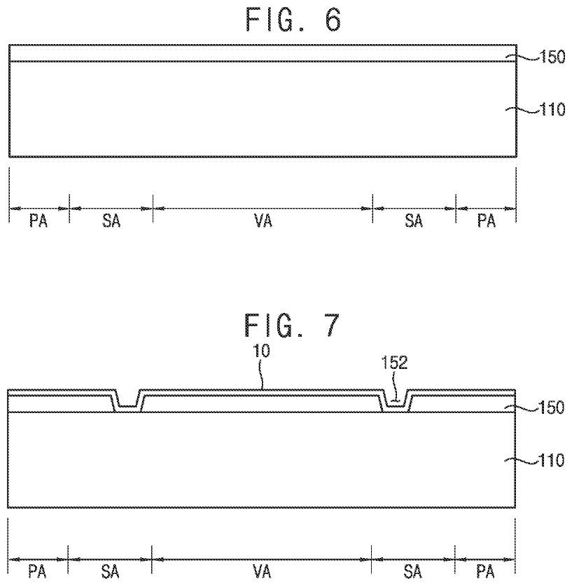

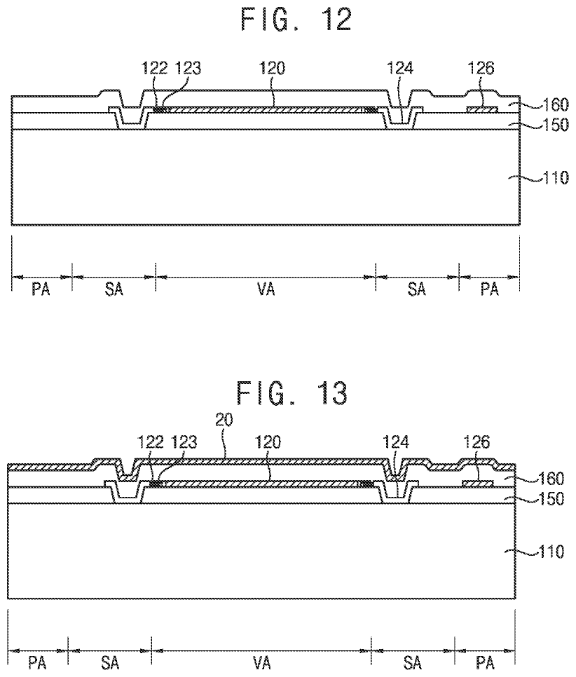

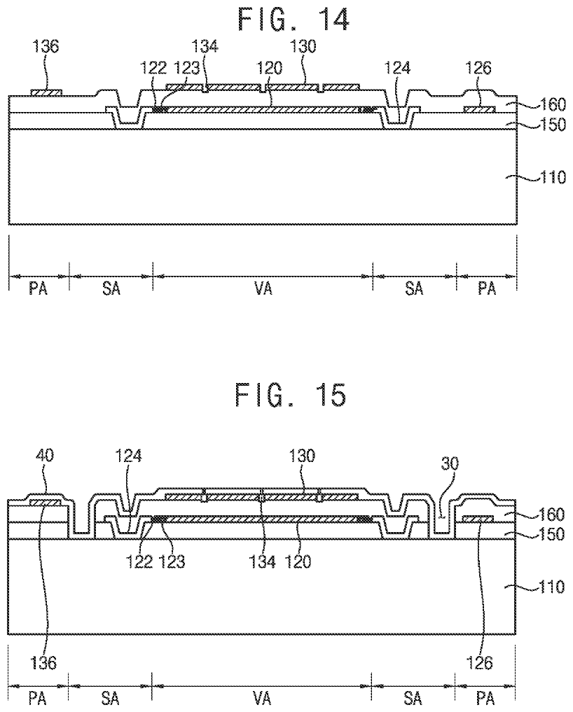

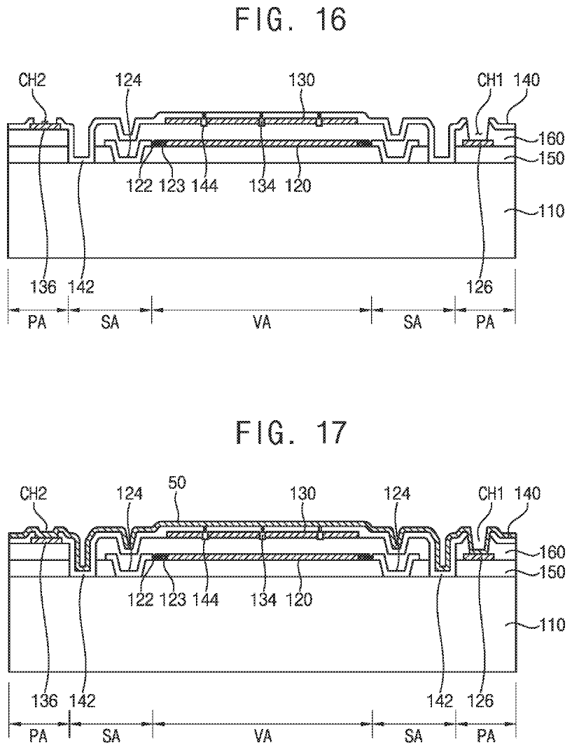

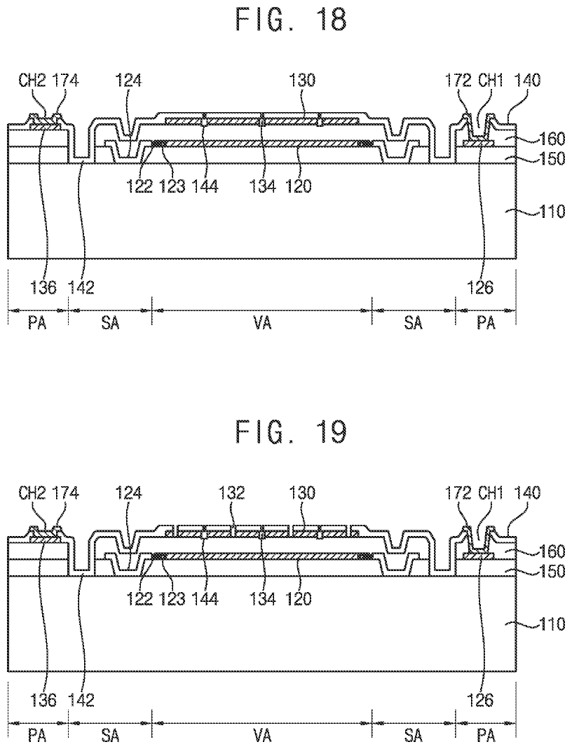

FIG. 5 is a flow chart illustrating a method of manufacturing a MEMS microphone in accordance with an example embodiment of the present invention. FIGS. 6 to 21 are cross sectional views illustrating a method of manufacturing a MEMS microphone in accordance with an example embodiment of the present invention.

Referring to FIGS. 5 and 6, according to example embodiments of a method for manufacturing a MEMS microphone, a lower insulation layer 150 is formed on a substrate 110 at S110.

The lower insulation layer 150 may be formed by a deposition process. The lower insulation layer 150 may be made of an oxide such as silicon oxide or tetraethyl orthosilicate (TEOS).

Referring to FIGS. 5 and 7 to 11, a diaphragm 120, vent holes 122, an anchor 124, and a diaphragm pad 126 are formed on the lower insulation layer 150 at S120.

Hereinafter, S120 (forming the diaphragm 120, the vent holes 122, the anchor 124, and the diaphragm pad 126) will be in explained in further detail.

The lower insulation layer 150 is patterned through an etching process to form anchor channels 152 for forming the anchor 124. The anchor channels 152 may partially expose the substrate 110. The anchor channels 152 may be formed in the supporting area SA. For example, each of the anchor channels 152 may be formed to have a ring shape to surround a vibration area VA.

Next, a first silicon layer 10 is formed on the lower insulation layer 150 on which the anchor channels 152 are formed. The first silicon layer 10 may be formed by a deposition process. The first silicon layer 10 may be formed using polysilicon. The first silicon layer 10 may include the lower silicon layer 10a, the intermediate silicon layer 10b, and the upper silicon layer 10c. A plurality of vent holes 122 may also be formed while forming the silicon layer 10. The vent holes 122 are located in the vibration area VA.

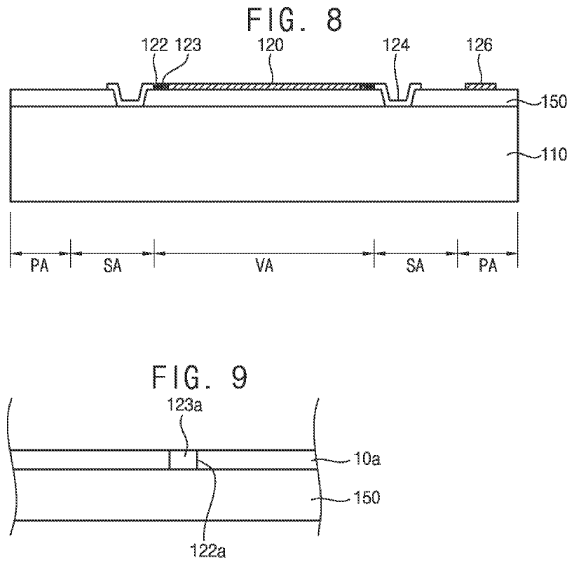

As shown in FIG. 9, to form the vent holes 122, first a lower silicon layer 10a is formed on the lower insulation layer 150 on which the anchor channel 152 is formed.

The lower silicon layer 10a is patterned through an etching process to form lower portions 122a penetrating the lower silicon layer 10a.

A first filling insulation layer pattern 123a filling the lower portions 122a is formed through a deposition process. The first filling insulation layer pattern 123a may be formed of an oxide such as silicon oxide or TEOS.

After the first filling insulation layer pattern 123a is formed, a surface of the first filling insulation layer pattern 123a may be planarized through a chemical mechanical polishing process.

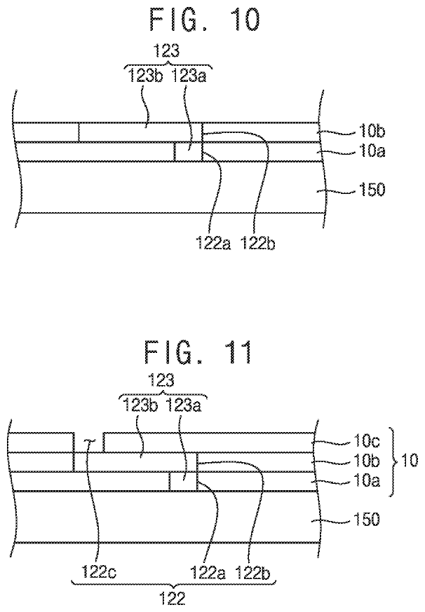

Referring to FIG. 10, an intermediate silicon layer 10b is formed on the lower silicon layer 10a on which the first filling insulation layer pattern 123a is formed.

The intermediate silicon layer 10b is patterned through an etching process to form intermediate portions 122b passing through the intermediate silicon layer 10b and respectively connected to the lower portions 122a. The intermediate portions 122b may have various shapes, such as a straight shape, a bent straight shape, a curved shape, and the like.

Thereafter, a second filling insulation layer pattern 123b filling the intermediate portions 122b is formed through a deposition process. The second filling insulation layer pattern 123b may be formed of an oxide such as silicon oxide or TEOS.

After the second filling insulation film pattern 123b is formed, a surface of the second filling insulation film pattern 123b may be planarized through a chemical mechanical polishing process.

Referring to FIG. 11, an upper silicon layer 10c is formed on the intermediate silicon layer 10b on which the second filling insulation layer pattern 123b is formed.

The upper silicon layer 10c is patterned through an etching process to form upper portions 122c passing through the upper silicon layer 10c and connected to the intermediate portions 122b, respectively.

The first filling insulation layer pattern 123a and the second filling insulation layer pattern 123b may form a filling insulation layer pattern 123 filling the lower portions 122a and the intermediate portions 122b. A material of the filling insulation layer pattern 123 may be the same as that of the lower insulation layer 150.

The lower portion 122a and the upper portion 122c may be spaced apart from each other in a direction parallel to the diaphragm 120 so that the vent holes 122 have a bent shape.

In an example embodiment of the present invention, the lower portion 122a and the upper portion 122c may be spaced apart from each other in a radial direction of the diaphragm 120 having a circular disc shape.

In an example embodiment of the present invention, the lower portion 122a and the upper portion 122c may be spaced apart from each other along a circumferential direction of the diaphragm 120 having the circular disc shape.

Since each of the vent holes 122 includes the lower portion 122a, the intermediate portion 122b, and the upper portion 122c, the vent holes 122 may have a bent shape. Accordingly, a length of the vent holes 122 may be increased.

Next, impurities may be doped into both a portion of the first silicon layer 10 positioned in the vibration area VA and a portion of the first silicon layer 10 to be subsequently transformed into a diaphragm pad 126 through an ion implantation process.

Then, the first silicon layer 10 is patterned to form a diaphragm 120 and the anchor 124, and the diaphragm pad 126 is formed in a peripheral area PA, as shown in FIG. 8.

In an example embodiment, the anchor 124 is formed along a circumference of the diaphragm 120 in the supporting area SA. The anchor 124 may have a ring shape.

In an example embodiment, the anchor 124 may be plural and may be disposed along a circumference of the diaphragm 120. Specifically, the anchors 124 may have a columnar shape spaced apart from each other. Each of the anchors 124 may have a U-shaped vertical section. In particular, an empty space may be formed between two adjacent anchors among the anchors 124, and the empty space may act as a passage through which the acoustic wave moves. Further, the empty space may also function as a passage for an etchant to remove the lower insulation layer 150 and the intermediate insulation layer 160 in a process of manufacturing the MEMS microphone 100.

Referring to FIGS. 5 and 12, an intermediate insulation layer 160 is formed on the lower insulation layer 150 to cover the diaphragm 120, the vent holes 122, the anchor 124, and the diaphragm pad 126 at S130.

The intermediate insulation layer 160 may be formed by a deposition process. The intermediate insulation layer 160 may be made of the same material as the lower insulation layer 150 and the filling insulation layer pattern 123. The intermediate insulation layer 160 may be formed of an oxide such as silicon oxide or TEOS.

The intermediate insulation layer 160 may fill the upper portions 122c of the vent holes 122. Accordingly, the vent holes 122 may be filled with the oxide.

Referring to FIGS. 5, 13, and 14, a back plate 130 and a back plate pad 136 are formed on the intermediate insulation layer 160 at S140.

In particular, a second silicon layer 20 is formed on an upper surface of the intermediate insulation layer 160. Then, impurities are doped with the second silicon layer 20 by an ion implantation process. In an example embodiment, the second silicon layer 20 may be formed using polysilicon.

Next, the second silicon layer 20 is patterned to form dimple holes 134 for forming dimples 144 (see FIG. 2). The dimple holes 134 may be formed in the vibration area VA. Specifically, the dimple holes 134 may be disposed in a portion where the back plate 130 is to be formed. A portion of the intermediate insulation layer 160 corresponding to the dimple holes 134 may be etched to cause the dimples 144 to protrude downwardly from a lower surface of the back plate 130.

Further, the second silicon layer 20 is patterned to form the back plate 130 and the back plate pad 136. The back plate 130 may be formed in the vibration area VA, and the back plate pad 136 may be formed in the peripheral area PA.

Referring to FIGS. 5, 15 and 16, an upper insulation layer 140 and a strut 142 are formed on the intermediate insulation layer 160 on which the back plate 130 and the back plate pad 136 are formed at S150.

In particular, the intermediate insulation layer 160 and the lower insulation layer 150 are patterned to form a strut channel 30 in the supporting area SA for forming a strut 142 (see FIG. 2). The strut channel 30 may partially expose the supporting area SA of the substrate 110. Even though not shown in detail, the strut channel 30 may have a ring shape to surround the diaphragm 120.

After an insulation layer 40 is formed on the intermediate insulation layer 160 having the strut channel 30, the insulation layer 40 is patterned to form an upper insulation layer 140 and the strut 142.

Further, the dimples 144 may be further formed in the dimple holes 134 by depositing the insulation layer 40.

A second contact hole CH2 is formed in the peripheral area PA to expose the back plate pad 136 by patterning the insulation layer 40. Furthermore, both a portion of the insulation layer 40 and a portion of the intermediate insulation layer 160, positioned over the diaphragm pad 126, are removed to form a first contact hole CH1. The diaphragm pad 126 is exposed through the first contact hole CH1.

In an example embodiment, the upper insulation layer 140 may be formed using a material different from those of the lower insulation layer 150 and the intermediate insulation layer 160. In one example embodiment, the upper insulation layer 140 is formed using a nitride such as silicon nitride or silicon oxynitride, whereas the lower insulation layer 150 and the intermediate insulation layer 160 are formed using the oxide such as silicon oxide.

Referring to FIGS. 5, 17 and 18, a first pad electrode 172 and a second pad electrode 174 may be formed in after the first and the second contact holes CH1 and CH2 in the peripheral area PA at S160.

A thin layer 50 is formed on the upper insulation layer 140 through which the first and the second contact holes CH1 and CH2 are formed. In an example embodiment, the thin layer 50 may be formed using a conductive metal such as aluminum.

Next, the thin layer 50 is patterned to form a first pad electrode 172 and a second pad electrode 162. Here, the first pad electrode 172 may be formed on the diaphragm pad 126, and the second pad electrode 174 may be formed on the back plate pad 136.

Referring to FIGS. 5 and 19, the upper insulation layer 140 and the back plate 130 are patterned to form acoustic holes 132 in the vibration area VA at S170.

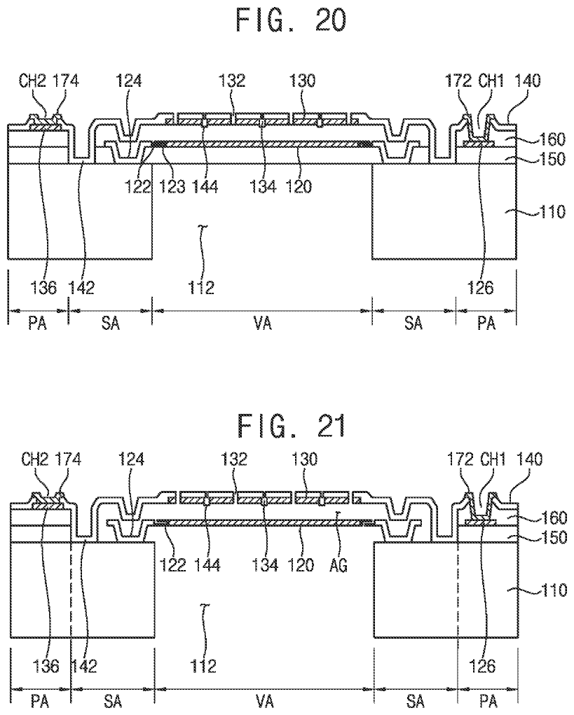

Referring to FIGS. 5 and 20, after forming the acoustic holes 132, the substrate 110 is patterned to form a cavity 112 in the vibration area VA at S180. Here, a portion of the lower insulation layer 150 is exposed through the cavity 112.

Referring to FIGS. 5 and 21,

Portions of the intermediate insulation layer 160 and the lower insulation layer 150, corresponding to the vibration area VA and the supporting area SA, and the filling insulation layer pattern 123 are removed through an etching process using the cavity 112, the acoustic holes 132, and the vent holes 122 at S190.

Thus, the diaphragm 120 is exposed through the cavity 112, and an air gap AG is formed. Further, the intermediate insulation layer 160 and the lower insulation layer 150 are formed. Here, the cavity 112, the acoustic holes 132, and the vent holes 122 may also act as passages of etchant for removing the portions of the lower insulation layer 150 and the intermediate insulation layer 160.

In addition, the anchor 124 and strut 142 may function to restrict the flow of the etchant during the removal of the intermediate insulation layer 160 and the lower insulation layer 150 from the vibration area VA and the support area SA. Therefore, an etching amount of the intermediate insulation layer 160 and the lower insulation layer 150 may be adjusted to prevent the lower insulation layer 150 from remaining inside of the anchor 124.

In an example embodiment of the present invention, a hydrogen fluoride vapor

(HF vapor) may be used as the etchant for removing the intermediate insulation layer 160 and the lower insulation layer 150.

As described above, according to the methods of manufacturing a MEMS microphone of the present invention, each of the vent holes 122 may have a bent shape including the lower portion 122a, the intermediate portion 122b and the upper portion 122c. Thus, the length of the vent holes 122 may be increased. Since the length of the vent holes 122 is increased, resistance acting on the acoustic wave passing through the vent holes 122 may increase. As a result, since the vent holes 122 may be remarkably weakened a noise component of a high frequency in the acoustic wave as compared with the conventional vent hole, and a SNR of the MEMS microphone may be improved.

In addition, the strut 142 may function to restrict the flow of the etchant during the removal of the intermediate insulation layer 160 and the lower insulation layer 150 from the vibration area VA and the support area SA. Therefore, the etching amount of the intermediate insulation layer 160 and the lower insulation layer 150 may be adjusted.

Further, since the etchant may be moved through the vent holes 122 of the diaphragm 120 during the manufacturing process of the MEMS microphone, the process efficiency can be improved.

Although the MEM microphone has been described with reference to the specific embodiments, they are not limited thereto. Therefore, it will be readily understood by those skilled in the art that various modifications and changes can be made thereto without departing from the spirit and scope of the appended claims.

Various embodiments of systems, devices and methods have been described herein. These embodiments are given only by way of example and are not intended to limit the scope of the invention. It should be appreciated, moreover, that the various features of the embodiments that have been described may be combined in various ways to produce numerous additional embodiments. Moreover, while various materials, dimensions, shapes, configurations and locations, etc. have been described for use with disclosed embodiments, others besides those disclosed may be utilized without exceeding the scope of the invention.

Persons of ordinary skill in the relevant arts will recognize that the invention may comprise fewer features than illustrated in any individual embodiment described above. The embodiments described herein are not meant to be an exhaustive presentation of the ways in which the various features of the invention may be combined. Accordingly, the embodiments are not mutually exclusive combinations of features; rather, the invention can comprise a combination of different individual features selected from different individual embodiments, as understood by persons of ordinary skill in the art. Moreover, elements described with respect to one embodiment can be implemented in other embodiments even when not described in such embodiments unless otherwise noted. Although a dependent claim may refer in the claims to a specific combination with one or more other claims, other embodiments can also include a combination of the dependent claim with the subject matter of each other dependent claim or a combination of one or more features with other dependent or independent claims. Such combinations are proposed herein unless it is stated that a specific combination is not intended. Furthermore, it is intended also to include features of a claim in any other independent claim even if this claim is not directly made dependent to the independent claim.

Any incorporation by reference of documents above is limited such that no subject matter is incorporated that is contrary to the explicit disclosure herein. Any incorporation by reference of documents above is further limited such that no claims included in the documents are incorporated by reference herein. Any incorporation by reference of documents above is yet further limited such that any definitions provided in the documents are not incorporated by reference herein unless expressly included herein.

For purposes of interpreting the claims for the present invention, it is expressly intended that the provisions of Section 112(f) of 35 U.S.C. are not to be invoked unless the specific terms “means for” or “step for” are recited in a claim.

What is claimed is:

1. A diaphragm of a Micro-Electro-Mechanical Systems (MEMS) microphone configured to generate a displacement thereof in response to an applied acoustic pressure, the diaphragm comprising:
a plurality of vent holes having a bent shape to increase the length of the vent holes.

2. The diaphragm of claim 1, wherein each of the vent holes includes:
a lower portion extending from a lower surface of the diaphragm to an inside of the diaphragm;
an intermediate portion connected to the lower portion in the inside of the diaphragm and extending in a direction parallel to the diaphragm; and
an upper portion connected to the intermediate portion in the inside of the diaphragm and extending to an upper surface of the diaphragm.

3. A MEMS microphone comprising:
a substrate presenting a vibration area, a supporting area surrounding the vibration area and a peripheral area surrounding the supporting area, the substrate defining a cavity formed in the vibration area;
a diaphragm disposed in the vibration area, being spaced apart from the substrate, covering the cavity, and configured to generate a displacement thereof in response to an applied acoustic pressure, the diaphragm defining a plurality of vent holes; and
a back plate disposed over the diaphragm in the vibration area, the back plate being spaced apart from the diaphragm to maintain an air gap between the back plate and the diaphragm, the back plate defining a plurality of acoustic holes,
wherein the vent holes have a bent shape to increase the length of the vent holes.

4. The MEMS microphone of claim 3, wherein each of the vent holes includes:
a lower portion extending from a lower surface of the diaphragm to an inside of the diaphragm;
an intermediate portion connected to the lower portion in the inside of the diaphragm and extending in a direction parallel to the diaphragm; and
an upper portion connected to the intermediate portion in the inside of the diaphragm and extending to an upper surface of the diaphragm.

5. A method of manufacturing a MEMS microphone comprising:
forming a lower insulation layer on a substrate, the substrate having a vibration area, a supporting area surrounding the vibration area, and a peripheral area surrounding the supporting area;
forming a diaphragm on the lower insulation layer, the diaphragm disposed in the vibration area and having a plurality of vent holes;
forming an intermediate insulation layer on the lower insulation layer covering the diaphragm;
forming a back plate on the intermediate insulation layer in the vibration area facing the diaphragm; and
forming an upper insulation layer on the intermediate insulation layer configured to hold the back plate apart from the diaphragm,
wherein the vent holes have a bent shape to increase the length of the vent holes.

6. The method of claim 5, wherein forming the diaphragm comprises:
forming a lower silicon layer on the lower insulation layer in the vibration area;
patterning the lower silicon layer through an etching process to form lower portions penetrating the lower silicon layer;
forming a first filling insulation layer pattern filling the lower portions;
forming an intermediate silicon layer on the lower silicon layer;
patterning the intermediate silicon layer through an etching process to form intermediate portions penetrating the intermediate silicon layer, and respectively connected to the lower portions;
forming a second filling insulation layer pattern filling the intermediate portions;
forming an upper silicon layer on the intermediate silicon layer; and
patterning the upper silicon layer through an etching process to form upper portions penetrating the upper silicon layer and respectively connected to the intermediate portions,
wherein each of the vent holes includes the lower portion, the intermediate portion, and the upper portion.

7. The method of claim 6, wherein the intermediate insulation layer fills the upper portions when forming the intermediate insulation layer on the lower insulation layer covering the diaphragm.

8. The method of claim 6, wherein the lower insulation layer, the intermediate insulation layer, the first filling insulation layer and the second filling insulation layer are made of the same oxide.

9. The method of claim 6, further comprising:
patterning the back plate and the upper insulation layer to form a plurality of acoustic holes penetrating through the back plate and the upper insulation layer;
patterning the substrate to form a cavity in the vibration area to partially expose the lower insulation layer; and
performing an etching process whereby an etchant is passed through the cavity and the acoustic holes to remove portions of the intermediate insulation layer, the lower insulation layer, the first filling insulation layer pattern, and the second filling insulation layer pattern, each of the removed portions located at positions corresponding the vibration area and the supporting area.

10. The method of claim 9, wherein the vent holes provide passage for the etchant during the etching process.
